(19) United States
(12) Patent Application Publication
(10) Pub. No.: US 2025/0321550 A1
(43) Pub. Date: Oct. 16, 2025

(54) METHOD AND SYSTEM FOR CONTROLLING RESISTIVITY BASED ON GALLIUM CONTENT IN GALLIUM-DOPED SINGLE CRYSTAL, AND DEVICE

(71) Applicants: GOKIN SOLAR CO., LTD., Zhuhai, Guangdong (CN); QINGHAI GOKIN SOLAR TECHNOLOGY CO., LTD., Xining, Qinghai (CN)

(72) Inventors: Zhiqun XU, Zhuhai, Guangdong (CN); Qi WANG, Zhuhai, Guangdong (CN); Bin SUN, Zhuhai, Guangdong (CN); Le QIAO, Zhuhai, Guangdong (CN); Weiping MA, Zhuhai, Guangdong (CN)

(73) Assignees: GOKIN SOLAR CO., LTD., Zhuhai, Guangdong (CN); QINGHAI GOKIN SOLAR TECHNOLOGY CO., LTD., District Xining, Qinghai (CN)

(21) Appl. No.: 18/870,569

(22) PCT Filed: Apr. 25, 2023
(86) PCT No.: PCT/CN2023/090484

§ 371 Date: Nov. 29, 2024

(30) Foreign Application Priority Data
May 31, 2022 (CN) 202210603932.X

(51) Int. Cl. G05B 13/04; G01R 27/08

(52) U.S. Cl. CPC G05B 13/04; G01R 27/08

(57) ABSTRACT

The present disclosure provides a method and system for controlling resistivity based on gallium content in a gallium-doped single crystal, and a device. The method includes: an initial gallium doping reference value is set, resistivity measurement values are obtained in real time; a first over-limit command and a second over-limit command are sent when one of the resistivity measurement values satisfies a preset condition; a target prediction value is calculated based on the resistivity measurement values; online analysis is performed to generate a reference value increment and a fluctuation adjustment instruction; and a gallium doping amount reference value is modified in real time based on the initial gallium doping reference value, the reference value increment, the first over-limit command, the second over-limit command, and the fluctuation adjustment instruction, and a resistivity fluctuation is controlled based on a modified gallium doping amount reference value.

### CROSS-REFERENCE TO RELATED APPLICATION

The disclosure takes the patent file No. 202210603932.X, filed on May 31, 2022 and entitled “METHOD AND SYSTEM FOR CONTROLLING RESISTIVITY BASED ON GALLIUM CONTENT IN GALLIUM-DOPED SINGLE CRYSTAL, AND DEVICE” as the priority file, which is incorporated in its entirety herein by reference.

### TECHNICAL FIELD

The present disclosure relates to the technical field of photovoltaic power generation devices, and more specifically, to a method and system for controlling resistivity based on gallium content in a gallium-doped single crystal, a non-transitory computer-readable storage medium, and an electronic device.

### BACKGROUND

To reduce the costs of electricity in photovoltaic power stations, current research has been focusing on reducing the production costs of silicon materials, wafers, batteries, and assemblies, as well as improving battery efficiency and assembly power. The assembly power is increased by not only improving battery efficiency and module technologies, but a simple method of increasing the wafer area. Therefore, in recent years, the wafer size has become larger. The photovoltaic industry has always used boron-doped P-type silicon wafers because boron has a segregation coefficient closest to 1 in silicon, making it easiest to obtain P-type silicon wafers with stable resistivity. However, this also brings a series of problems. For example, the boron-oxygen (BO) complex in silicon causes significant degradation of the efficiency of solar batteries.

Before the technologies of the present disclosure, in recent years, the gallium-doped single crystal has been used because it contains no boron and thus does not form the BO complex, fundamentally resolving the problem of single crystal degradation. However, during the Czochralski process of pulling a single crystal, gallium at the edge of the crystallization surface easily volatilizes. After each segment of the single crystal is pulled, the actual remaining gallium in the crucible is lower than the theoretical amount. The theoretically simulated and calculated gallium doping amount is lower than the actual amount, leading to a continuous increase in resistivity as the pulled segments increase. In the current calculation of the dopant amount, the single crystal pulled in one batch is divided into two parts for resistivity control, with the resistivity in both parts showing an upward trend for each segment, significantly affecting the resistivity concentration and ultimately causing a large fluctuation in the resistivity of the single crystal.

### SUMMARY

The present disclosure provides a method and system for controlling resistivity based on gallium content in a gallium-doped single crystal, a non-transitory computer-readable storage medium, and an electronic device.

A first aspect of the embodiments of the present disclosure provides a method for controlling resistivity based on gallium content in a gallium-doped single crystal.

In one or more embodiments, preferably, the method for controlling resistivity based on the gallium content in the gallium-doped single crystal includes:
an initial gallium doping reference value is set for the gallium-doped single crystal, and resistivity measurement values of the gallium-doped single crystal are obtained in real time using a sensor;
a first over-limit command and a second over-limit command are sent when one of the resistivity measurement values satisfies a preset condition;
a target optimal prediction coefficient group is calculated based on the resistivity measurement values;
a target prediction value is calculated based on the target optimal prediction coefficient group;
online analysis is performed based on the target prediction value to generate a reference value increment and a fluctuation adjustment instruction; and
a gallium doping amount reference value of the gallium-doped single crystal is modified in real time based on the initial gallium doping reference value, the reference value increment, the first over-limit command, the second over-limit command, and the fluctuation adjustment instruction, and a resistivity fluctuation of the gallium-doped single crystal is controlled based on the modified gallium doping amount reference value; and
the first over-limit command and the second over-limit command are used for cooperation with the fluctuation adjustment instruction to enable real-time control of the gallium doping amount reference value; the target optimal prediction coefficient group is used for representing a prediction function coefficient set corresponding to most accurate prediction data; the target prediction value is prediction data obtained at a future t+1-th time point based on the target optimal prediction coefficient group; and the reference value increment is a real-time variation of the gallium doping amount reference value during real-time modification of the gallium doping amount reference value.

In one or more embodiments, preferably, the initial gallium doping reference value is set for the gallium-doped single crystal, and the resistivity measurement values of the gallium-doped single crystal are obtained in real time using a sensor includes:
based on a preset parameter of the gallium-doped single crystal, the initial gallium doping reference value is set;
resistivity of the gallium-doped single crystal are measured in real time by a voltage sensor and a current sensor; and
a time of the resistivity obtained through measurement is marked, and the resistivity after time marking is taken as the resistivity measurement values.

In one or more embodiments, preferably, the first over-limit command and the second over-limit command are sent when one of the resistivity measurement values satisfies the preset condition includes:
a resistivity measurement value at an initial time point is set;
a resistivity measurement value, at a current time point, is read used as a resistivity measurement value at a t-th time point;
the resistivity fluctuation is calculated according to a first calculation formula;
it is determined whether the resistivity fluctuation satisfies a second calculation formula; and in a case that the resistivity fluctuation satisfies the second calculation formula, the first over-limit command is sent; or in a case that the resistivity fluctuation does not satisfy the second calculation formula, operation is continued without processing; and
it is determined whether the resistivity fluctuation satisfies a third calculation formula; and in a case that the resistivity fluctuation satisfies the third calculation formula, the second over-limit command is sent; or in a case that the resistivity fluctuation does not satisfy the third calculation formula, the operation is continued without processing; and
the first calculation formula is:

$$B = {D}_{t} - {D}_{0} ,$$

B represents the resistivity fluctuation, Dₜ represents the resistivity measurement value at the t-th time point, and D₀ represents the resistivity measurement value at the initial time point;
the second calculation formula is:

$$B 〉 {L}_{1} 〉 0.5 ,$$

L₁ represents a preset first resistivity fluctuation limit; and
the third calculation formula is:

$$B 〉 {L}_{2} 〉 0.75 〉 {L}_{1} ,$$

L₂ represents a preset second resistivity fluctuation limit.

In one or more embodiments, preferably, the target optimal prediction coefficient group is calculated based on the resistivity measurement value includes:
a first prediction coefficient, a second prediction coefficient, a third prediction coefficient, a fourth prediction coefficient, and a fifth prediction coefficient are set;
stored historical data of the resistivity measurement values are read;
a predicted resistivity value is calculated according to a fourth calculation formula;
based on the predicted resistivity value, according to a fifth calculation formula, a first target prediction coefficient, a second target prediction coefficient, a third target prediction coefficient, a fourth target prediction coefficient, and a fifth target prediction coefficient are calculated; and
the first target prediction coefficient, the second target prediction coefficient, the third target prediction coefficient, the fourth target prediction coefficient, and the fifth target prediction coefficient are stored as the target optimal prediction coefficient group; and
the fourth calculation formula is:

$${Y}_{t + 1} = {k}_{1} {D}_{t} + {k}_{2} {D}_{t - 1} + {k}_{3} {D}_{t - 2} + {k}_{4} {D}_{t - 3} + {k}_{5} {D}_{t - 4} + D ,$$

Yₜ₊₁ represents the predicted resistivity value at a t+1-th time point, Dₜ₋₁ represents the resistivity measurement value at a t−1-th time point, Dₜ₋₂ represents the resistivity measurement value at a t−2-th time point, Dₜ₋₃ represents the resistivity measurement value at a t−3-th time point, Dₜ₋₄ represents the resistivity measurement value at a t−4-th time point, D represents an average resistivity value, and k₁, k₂, k₃, k₄, and k₅ sequentially represent the first prediction coefficient, the second prediction coefficient, the third prediction coefficient, the fourth prediction coefficient, and the fifth prediction coefficient, respectively; and
the fifth calculation formula is:

$$( {k}_{1 m} , {k}_{2 m} , {k}_{3 m} , {k}_{4 m} , {k}_{5 m} ) = arg min ( \vert {Y}_{t + 1} - {D}_{t + 1} \vert ) ,$$

argmin represents a function coefficient when a minimum value of a target function |Yₜ₊₁−Dₜ₊₁| is selected, Dₜ₊₁ represents an actual resistivity measurement value at the t+1-th time point, and k₁ₘ, k₂ₘ, k₃ₘ, k₄ₘ, and k₅ₘ sequentially represent the first target prediction coefficient, the second target prediction coefficient, the third target prediction coefficient, the fourth target prediction coefficient, and the fifth target prediction coefficient, respectively.

In one or more embodiments, preferably, the target prediction value is calculated based on the target optimal prediction coefficient group includes;
based on the resistivity measurement value at the current time point and the historical data of the resistivity measurement values, the average resistivity value is calculated; and
the target prediction value is calculated according to a sixth calculation formula; and
the sixth calculation formula is:

$${Y}_{M} = {k}_{1 m} {D}_{t} + {k}_{2 m} {D}_{t - 1} + {k}_{3 m} {D}_{t - 2} + {k}_{4 m} {D}_{t - 3} + {k}_{5 m} {D}_{t - 4} + D ,$$

Y_{M} represents the target prediction value, and k₁ₘ, k₂ₘ, k₃ₘ, k₄ₘ, and k₅ₘ sequentially represent the first target prediction coefficient, the second target prediction coefficient, the third target prediction coefficient, the fourth target prediction coefficient, and the fifth target prediction coefficient, respectively.

In one or more embodiments, preferably, the online analysis is performed based on the target prediction value to generate the reference value increment and the fluctuation adjustment instruction includes:
it is determined whether the target prediction value satisfies a seventh calculation formula, and in a case that the target prediction value satisfies the seventh calculation formula, the fluctuation adjustment instruction is generated;
after the fluctuation adjustment instruction is generated, the resistivity measurement value at the initial time point and the average resistivity value are automatically read; and
the reference value increment is calculated according to an eighth calculation formula; and
the seventh calculation formula is:

$${Y}_{M} 〉 1 ,$$

and
the eighth calculation formula is:

$${D}_{Ref} = ( D - {Y}_{M} ) / {D}_{0} ,$$

D_{Ref} represents the reference value increment.

In one or more embodiments, preferably, the gallium doping amount reference value of the gallium-doped single crystal is modified in real time based on the initial gallium doping reference value, the reference value increment, the first over-limit command, the second over-limit command, and the fluctuation adjustment instruction, and the resistivity fluctuation of the gallium-doped single crystal is controlled based on the modified gallium doping amount reference value includes:
a sum of the initial gallium doping reference value and the reference value increment is taken as a real-time adjustment parameter;
it is determined, based on a preset time period, whether there is the first over-limit command, in a case that there is the first over-limit command, it is continued to determine whether there is the fluctuation adjustment instruction, and in a case that there is the fluctuation adjustment instruction, a 50% control command is sent to a control device for gallium doping amount, such that when the control device for gallium doping amount receives the 50% control command, the gallium doping amount reference value is modified as the real-time adjustment parameter only within half of an operation time during operation;
it is determined, based on the preset time period, whether there is the second over-limit command, in a case that there is the second over-limit command, it is continued to determine whether there is the fluctuation adjustment instruction, and in a case that there is the fluctuation adjustment instruction, a 100% control command is sent to the control device for gallium doping amount, such that when the control device for gallium doping amount receives the 100% control command, the gallium doping amount reference value is modified as the real-time adjustment parameter within the whole operation time during operation; and
the resistivity fluctuation of the gallium-doped single crystal is controlled based on the modified gallium doping amount reference value.

A second aspect of the embodiments of the present disclosure provides a system for controlling resistivity based on gallium content in a gallium-doped single crystal.

In one or more embodiments, preferably, the system for controlling resistivity based on the gallium content in the gallium-doped single crystal includes:
a resistivity collection module configured to set an initial gallium doping reference value for the gallium-doped single crystal, and obtain resistivity measurement values of the gallium-doped single crystal in real time using a sensor;
a fluctuation analysis module configured to send a first over-limit command and a second over-limit command when one of the resistivity measurement values satisfies a preset condition;
a model training module configured to calculate a target optimal prediction coefficient group based on the resistivity measurement values;
a fluctuation prediction module configured to calculate a target prediction value based on the target optimal prediction coefficient group;
an increment operation module configured to perform online analysis based on the target prediction value to generate a reference value increment and a fluctuation adjustment instruction; and
a gallium-doping regulation module configured to modify a gallium doping amount reference value of the gallium-doped single crystal in real time based on the initial gallium doping reference value, the reference value increment, the first over-limit command, the second over-limit command, and the fluctuation adjustment instruction, and control a resistivity fluctuation of the gallium-doped single crystal based on a modified gallium doping amount reference value; and
the first over-limit command and the second over-limit command are used for cooperation with the fluctuation adjustment instruction to enable real-time control of the gallium doping amount reference value; the target optimal prediction coefficient group is used for representing a prediction function coefficient set corresponding to most accurate prediction data; the target prediction value is prediction data obtained at a future t+1-th time point based on the target optimal prediction coefficient group; and the reference value increment is a real-time variation of the gallium doping amount reference value during real-time modification of the gallium doping amount reference value.

A third aspect of the embodiments of the present disclosure provides a non-transitory computer-readable storage medium, storing a computer program instruction, where when the computer program instruction is executed by a processor, the method according to any one of the embodiments of the first aspect of the present disclosure is implemented.

A fourth aspect of the embodiments of the present disclosure provides an electronic device, including a memory and a processor, where the memory is configured to store one or more computer program instructions, and the one or more computer program instructions are executed by the processor to implement the method according to any one of the embodiments of the first aspect of the present disclosure.

Other features and advantages of the present disclosure will be illustrated in the following description, and some of these will become apparent from the description or be understood by implementing the present disclosure. The objectives and other advantages of the present disclosure may be achieved and derived from the structures indicated in the description, claims, and accompanying drawings.

The technical solution of the present disclosure is further described below in detail with reference to accompanying drawings and embodiments.

### BRIEF DESCRIPTION OF THE DRAWINGS

To describe the technical solutions in the embodiments of the present disclosure more clearly, the following briefly describes the accompanying drawings required in the description of the embodiments. Apparently, the accompanying drawings in the following description show only some embodiments of the present disclosure, and persons skilled in the art may still derive other drawings from these accompanying drawings without creative efforts.

FIG. 1 is a flowchart of a method for controlling resistivity based on gallium content in a gallium-doped single crystal according to an embodiment of the present disclosure.

FIG. 2 is a flowchart of setting an initial gallium doping reference for the gallium-doped single crystal and obtaining resistivity measurement values of the gallium-doped single crystal in real time using a sensor in the method for controlling resistivity based on the gallium content in the gallium-doped single crystal according to an embodiment of the present disclosure.

FIG. 3 is a flowchart of sending a first over-limit command and a second over-limit command when one of the resistivity measurement values satisfies a preset condition in the method for controlling resistivity based on the gallium content in the gallium-doped single crystal according to an embodiment of the present disclosure.

FIG. 4 is a flowchart of calculating a target optimal prediction coefficient group based on the resistivity measurement values in the method for controlling resistivity based on the gallium content in the gallium-doped single crystal according to an embodiment of the present disclosure.

FIG. 5 is a flowchart of calculating a target prediction value based on the target optimal prediction coefficient group in the method for controlling resistivity based on the gallium content in the gallium-doped single crystal according to an embodiment of the present disclosure.

FIG. 6 is a flowchart of performing online analysis based on the target prediction value to generate a reference value increment and a fluctuation adjustment instruction in the method for controlling resistivity based on the gallium content in the gallium-doped single crystal according to an embodiment of the present disclosure.

FIG. 7 is a flowchart of modifying a gallium doping amount reference value of the gallium-doped single crystal in real time based on the initial gallium doping reference value, the reference value increment, the first over-limit command, the second over-limit command, and the fluctuation adjustment instruction, and controlling a resistivity fluctuation of the gallium-doped single crystal based on the modified gallium doping amount reference value in the method for controlling resistivity based on the gallium content in the gallium-doped single crystal according to an embodiment of the present disclosure.

FIG. 8 is a structural diagram of a system for controlling resistivity based on gallium content in a gallium-doped single crystal according to an embodiment of the present disclosure.

FIG. 9 is a structural diagram of an electronic device according to an embodiment of the present disclosure.

### DETAILED DESCRIPTION OF THE EMBODIMENTS

In the description of the specification, claims, and the above drawings of the present disclosure, some processes include multiple operations appearing in a specific order. However, it should be clearly understood that these operations can be performed in an order different from that in which they appear herein or performed in parallel. The operation numbers such as 101 and 102, are merely used to distinguish different operations and do not represent any execution order. Additionally, the processes may include more or fewer operations, and these operations may be performed sequentially or in parallel. It should be noted that the terms “first,” “second,” and the like, used herein are to distinguish different messages, devices, modules, and the like, and do not represent sequential order or imply that “first” and “second” are of different types.

The following clearly and completely describes the technical solutions in the embodiments of the present disclosure with reference to the accompanying drawings in the embodiments of the present disclosure. Apparently, the described embodiments are only some rather than all of the embodiments of the present disclosure. All other embodiments obtained by persons skilled in the art based on the embodiments of the present disclosure without creative efforts shall fall within the protection scope of the present disclosure.

To reduce the costs of electricity in photovoltaic power stations, current research has been focusing on reducing the production costs of silicon materials, wafers, batteries, and assemblies, as well as improving battery efficiency and assembly power. The assembly power is increased by not only improving battery efficiency and module technologies, but a simple method of increasing the wafer area. Therefore, in recent years, the wafer size has become larger. The photovoltaic industry has always used boron-doped P-type silicon wafers because boron has a segregation coefficient closest to 1 in silicon, making it easiest to obtain P-type silicon wafers with stable resistivity. However, this also brings a series of problems. For example, the boron-oxygen (BO) complex in silicon causes significant degradation of the efficiency of solar batteries.

Before the technologies of the present disclosure, in recent years, the gallium-doped single crystal has been used because it contains no boron and thus does not form the BO complex, fundamentally resolving the problem of single crystal degradation. However, during the Czochralski process of pulling a single crystal, gallium at the edge of the crystallization surface easily volatilizes. After each segment of the single crystal is pulled, the actual remaining gallium in the crucible is lower than the theoretical amount. The theoretically simulated and calculated gallium doping amount is lower than the actual amount, leading to a continuous increase in resistivity as the pulled segments increase. In the current calculation of the dopant amount, the single crystal pulled in one batch is divided into two parts for resistivity control, with the resistivity in both parts showing an upward trend for each segment, significantly affecting the resistivity concentration and ultimately causing a large fluctuation in the resistivity of the single crystal.

In this embodiment of the present disclosure, a method and system for controlling resistivity based on gallium content in a gallium-doped single crystal, a non-transitory computer-readable storage medium, and an electronic device are provided. In this solution, through calculation and collection of the gallium content in the gallium-doped single crystal, the problem of continuous resistivity increase due to gallium volatilization loss is resolved, with the resistivity fluctuation range of the single crystal controlled within 1.0%.

A first aspect of the embodiments of the present disclosure provides a method for controlling resistivity based on gallium content in a gallium-doped single crystal.

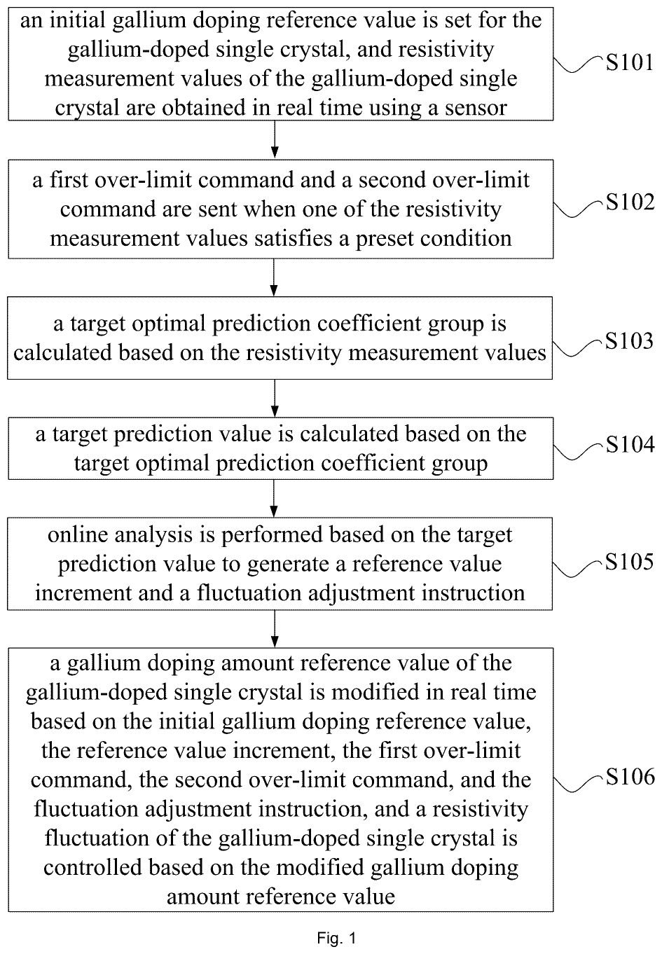

FIG. 1 is a flowchart of a method for controlling resistivity based on gallium content in a gallium-doped single crystal according to an embodiment of the present disclosure. The method includes the following steps:
S101. an initial gallium doping reference value is set for the gallium-doped single crystal, and resistivity measurement values of the gallium-doped single crystal are obtained in real time using a sensor;
S102. a first over-limit command and a second over-limit command are sent when one of the resistivity measurement values satisfies a preset condition;
S103. a target optimal prediction coefficient group is calculated based on the resistivity measurement values;
S104. a target prediction value is calculated based on the target optimal prediction coefficient group;
S105. online analysis is performed based on the target prediction value to generate a reference value increment and a fluctuation adjustment instruction; and
S106. a gallium doping amount reference value of the gallium-doped single crystal is modified in real time based on the initial gallium doping reference value, the reference value increment, the first over-limit command, the second over-limit command, and the fluctuation adjustment instruction, and a resistivity fluctuation of the gallium-doped single crystal is controlled based on the modified gallium doping amount reference value; and
the first over-limit command and the second over-limit command are used for cooperation with the fluctuation adjustment instruction to enable real-time control of the gallium doping amount reference value; the target optimal prediction coefficient group is used for representing a prediction function coefficient set corresponding to most accurate prediction data; the target prediction value is prediction data obtained at a future t+1-th time point based on the target optimal prediction coefficient group; and the reference value increment is a real-time variation of a control reference value of the gallium content of the gallium-doped single crystal.

It should be noted that the first over-limit command and the second over-limit command are two commands used for initiating the control of the gallium doping amount reference value. However, they need to cooperate with the fluctuation adjustment instruction to enable real-time control of the gallium doping amount reference value.

Prediction data is the original data not obtained through collection but pre-estimated through algorithms. The most accurate prediction data is prediction data with the smallest error obtained by comparing actual measured data with the predicted data. The prediction function is a function used for pre-estimating future time point data based on historical data and actual measured data. The prediction function coefficient set is a set of coefficients used for the operation of the prediction function.

In this embodiment of the present disclosure, to control the resistivity fluctuation within 1%, it is first necessary to analyze the head resistivity of each segment of the current single crystal production and determine the increased magnitude in resistivity of each segment. Then, based on the increased magnitude and the difference from the target resistivity to be achieved, the modification value for each segment is determined and increased. Finally, the modification value is periodically adjusted based on the actual effect of the single crystal production in each cycle to ensure control of the resistivity fluctuation.

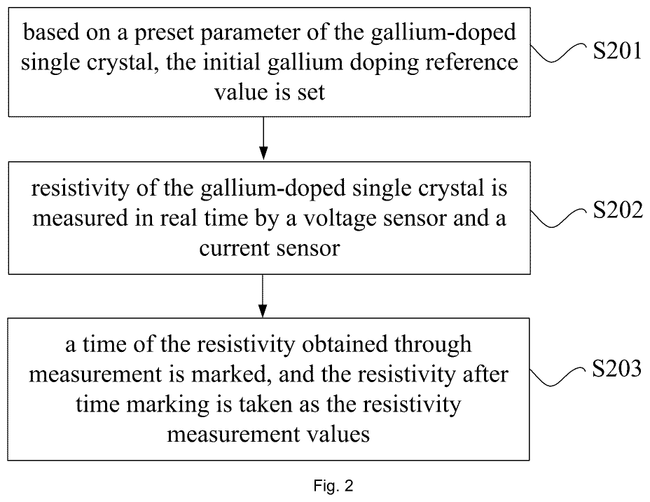

FIG. 2 is a flowchart of setting the initial gallium doping reference for the gallium-doped single crystal and obtaining the resistivity measurement values of the gallium-doped single crystal in real time using the sensor in the method for controlling resistivity based on the gallium content in the gallium-doped single crystal according to an embodiment of the present disclosure.

As shown in FIG. 2, in one or more embodiments, preferably, the initial gallium doping reference value is set for the gallium-doped single crystal, and the resistivity measurement values of the gallium-doped single crystal are obtained in real time using the sensor includes the following steps:
S201. based on a preset parameter of the gallium-doped single crystal, the initial gallium doping reference value is set;
S202. resistivity of the gallium-doped single crystal is measured in real time by a voltage sensor and a current sensor; and
S203. a time of the resistivity obtained through measurement is marked, and the resistivity after time marking is taken as the resistivity measurement values.

In this embodiment of the present disclosure, before the gallium-doped single crystal is controlled, data collection and acquisition are first performed. During this acquisition process, the resistivity at all time points is mainly collected by a sensor, and then the initial gallium doping reference value is set based on experience. However, this initial gallium doping reference value will be continuously replaced and modified in the subsequent process.

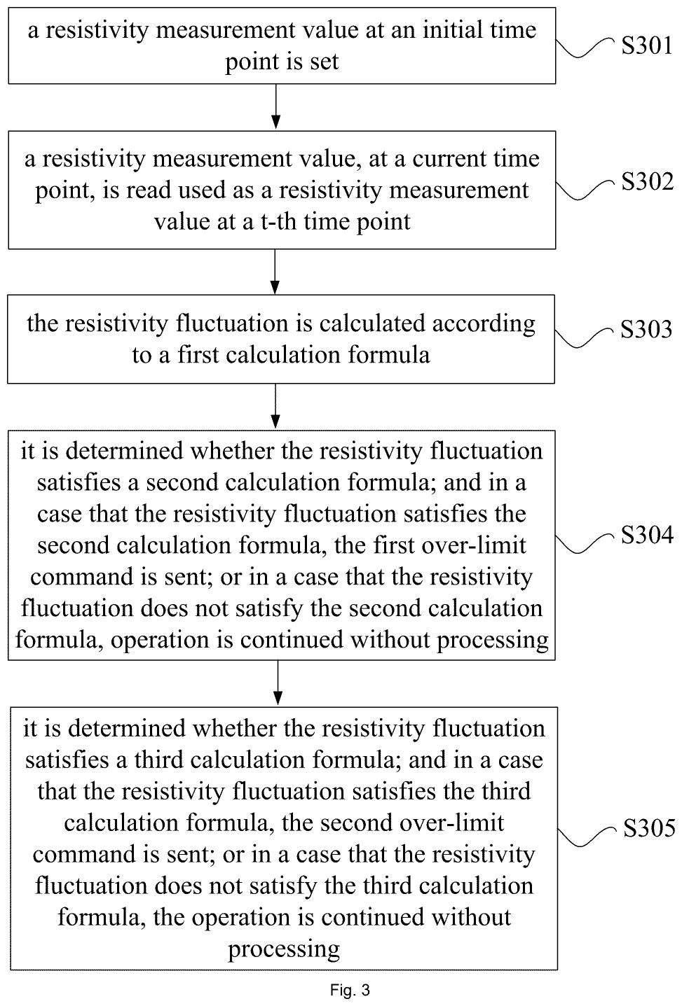

FIG. 3 is a flowchart of sending the first over-limit command and the second over-limit command when one of the resistivity measurement values satisfies the preset condition in the method for controlling resistivity based on the gallium content in the gallium-doped single crystal according to an embodiment of the present disclosure.

As shown in FIG. 3, in one or more embodiments, preferably, the first over-limit command and the second over-limit command are sent when one of the resistivity measurement values satisfies the preset condition includes the following steps:
S301. a resistivity measurement value at an initial time point is set;
S302. a resistivity measurement value, at a current time point, is read used as a resistivity measurement value at a t-th time point;
S303. the resistivity fluctuation is calculated according to a first calculation formula;
S304. it is determined whether the resistivity fluctuation satisfies a second calculation formula; and in a case that the resistivity fluctuation satisfies the second calculation formula, the first over-limit command is sent; or in a case that the resistivity fluctuation does not satisfy the second calculation formula, operation is continued without processing, that is, the operation of calculating the resistivity fluctuation is continued to perform; and
S305. it is determined whether the resistivity fluctuation satisfies a third calculation formula; and in a case that the resistivity fluctuation satisfies the third calculation formula, the second over-limit command is sent; or in a case that the resistivity fluctuation does not satisfy the third calculation formula, the operation is continued without processing; and
the first calculation formula is:

$$B = {D}_{t} - {D}_{0} ,$$

B represents the resistivity fluctuation, Dₜ represents the resistivity measurement value at the t-th time point, and D₀ represents the resistivity measurement value at the initial time point;
the second calculation formula is:

$$B 〉 {L}_{1} 〉 0.5 ,$$

L₁ represents a preset first resistivity fluctuation limit; and
the third calculation formula is:

$$B > {L}_{2} > 0.75 > {L}_{1} ,$$

L₂ represents a preset second resistivity fluctuation limit.

In the embodiments of the present disclosure, to achieve process control, two resistivity fluctuation limits are set. The first resistivity fluctuation limit L1 is for limiting a 0.5% resistivity change, while the second resistivity fluctuation limit L2 is for limiting a 0.75% resistivity change. The dual limits ensure real-time control of future resistivity changes.

For example, the first resistivity fluctuation limit L₁ and the second resistivity fluctuation limit L₂ are limits set based on actual operational requirements. The first resistivity fluctuation limit L₁ is smaller than the second resistivity fluctuation limit L₂. If there is no basic data, L₁ may be set to 0.6, and L₂ may be set to 0.8.

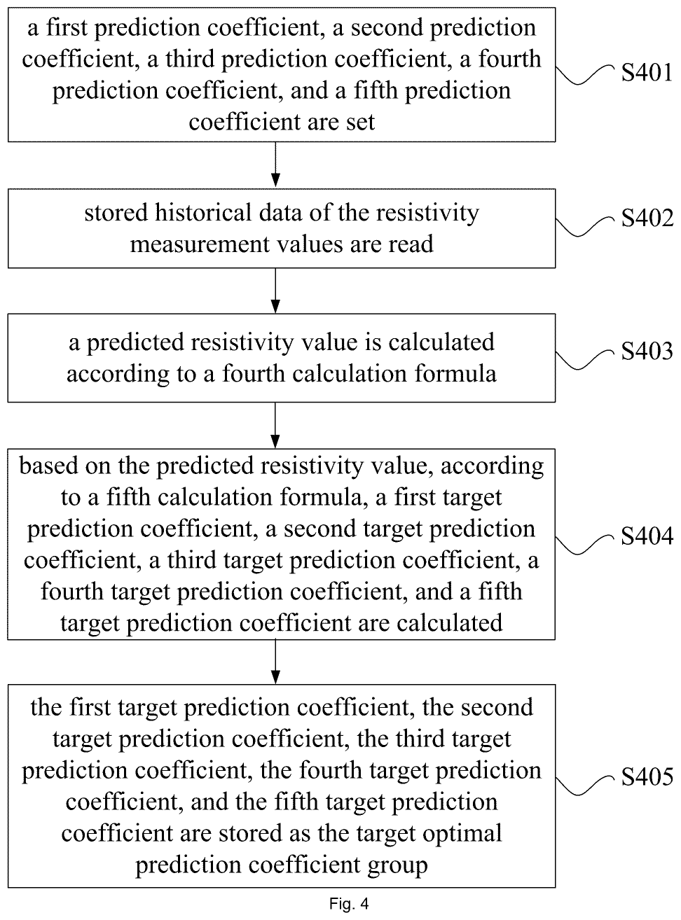

FIG. 4 is a flowchart of calculating the target optimal prediction coefficient group based on the resistivity measurement value in the method for controlling resistivity based on the gallium content in the gallium-doped single crystal according to an embodiment of the present disclosure.

As shown in FIG. 4, in one or more embodiments, preferably, the target optimal prediction coefficient group is calculated based on the resistivity measurement value includes the following steps:
S401. a first prediction coefficient, a second prediction coefficient, a third prediction coefficient, a fourth prediction coefficient, and a fifth prediction coefficient are set;
S402. stored historical data of the resistivity measurement values are read;
S403. a predicted resistivity value is calculated according to a fourth calculation formula;
S404. based on the predicted resistivity value, according to a fifth calculation formula, a first target prediction coefficient, a second target prediction coefficient, a third target prediction coefficient, a fourth target prediction coefficient, and a fifth target prediction coefficient are calculated; and
S405. the first target prediction coefficient, the second target prediction coefficient, the third target prediction coefficient, the fourth target prediction coefficient, and the fifth target prediction coefficient are stored as the target optimal prediction coefficient group; and
the fourth calculation formula is:

$${Y}_{t + 1} = {k}_{1} {D}_{t} + {k}_{2} {D}_{t - 1} + {k}_{3} {D}_{t - 2} + {k}_{4} {D}_{t - 3} + {k}_{5} {D}_{t - 4} + D ,$$

Yₜ₊₁ represents the predicted resistivity value at a t+1-th time point, Dₜ₋₁ represents the resistivity measurement value at a t−1-th time point, Dₜ₋₂ represents the resistivity measurement value at a t−2-th time point, Dₜ₋₃ represents the resistivity measurement value at a t−3-th time point, Dₜ₋₄ represents the resistivity measurement value at a t−4-th time point, D represents an average resistivity value, and k₁, k₂, k₃, k₄, and k₅ sequentially represent the first prediction coefficient, the second prediction coefficient, the third prediction coefficient, the fourth prediction coefficient, and the fifth prediction coefficient, respectively;
the fifth calculation formula is:

$$( {k}_{1 m} , {k}_{2 m} , {k}_{3 m} , {k}_{4 m} , {k}_{5 m} ) = arg min ( \vert {Y}_{t + 1} - {D}_{t + 1} \vert ) ,$$

argmin represents a coefficient corresponding to a target function when a minimum value of the target function is selected, Dₜ₊₁ represents an actual resistivity measurement value at the t+1-th time point, and k₁ₘ, k₂ₘ, k₃ₘ, k₄ₘ, and k₅ₘ sequentially represent the first target prediction coefficient, the second target prediction coefficient, the third target prediction coefficient, the fourth target prediction coefficient, and the fifth target prediction coefficient, respectively.

It should be noted that the calculation method for the average resistivity value is to take the resistivity measurement value at the current time point and the historical data of resistivity measurement values as all the resistivity measurement values, to sum up all the resistivity measurement values, and to divide the sum by the total number of corresponding resistivity measurement values.

In this embodiment of the present disclosure, to achieve a resistivity fluctuation of no more than 1%, continuous prediction is required. However, the prediction effect needs to be continuously learned and trained. In this embodiment, the model training is mainly considered, achieving the final model learning function as an adaptive changing function.

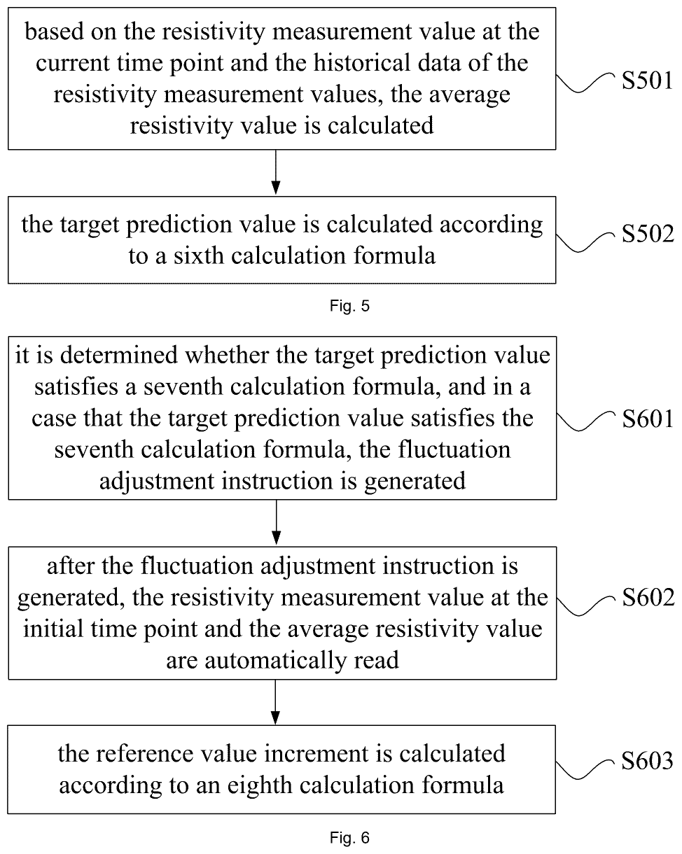

FIG. 5 is a flowchart of calculating the target prediction value based on the target optimal prediction coefficient group in the method for controlling resistivity based on the gallium content in the gallium-doped single crystal according to an embodiment of the present disclosure.

As shown in FIG. 5, in one or more embodiments, preferably, the target prediction value is calculated based on the target optimal prediction coefficient group includes the following steps:
S501. based on the resistivity measurement value at the current time point and the historical data of the resistivity measurement values, the average resistivity value is calculated; and
S502. the target prediction value is calculated according to a sixth calculation formula; and the sixth calculation formula is:

$${Y}_{M} = {k}_{1 m} {D}_{t} + {k}_{2 m} {D}_{t - 1} + {k}_{3 m} {D}_{t - 2} + {k}_{4 m} {D}_{t - 3} + {k}_{5 m} {D}_{t - 4} + D ,$$

Y_{M} represents the target prediction value, and k₁ₘ, k₂ₘ, k₃ₘ, k₄ₘ, and k₅ₘ sequentially represent the first target prediction coefficient, the second target prediction coefficient, the third target prediction coefficient, the fourth target prediction coefficient, and the fifth target prediction coefficient, respectively.

In this embodiment of the present disclosure, real-time calculation is performed for the current target prediction value. The calculation result provides guidance for the modification of control parameters.

FIG. 6 is a flowchart of performing online analysis based on the target prediction value to generate the reference value increment and the fluctuation adjustment instruction in the method for controlling resistivity based on the gallium content in the gallium-doped single crystal according to an embodiment of the present disclosure.

As shown in FIG. 6, in one or more embodiments, preferably, the online analysis is performed based on the target prediction value to generate the reference value increment and the fluctuation adjustment instruction includes the following steps:
S601. it is determined whether the target prediction value satisfies a seventh calculation formula, and in a case that the target prediction value satisfies the seventh calculation formula, the fluctuation adjustment instruction is generated;
S602. after the fluctuation adjustment instruction is generated, the resistivity measurement value at the initial time point and the average resistivity value are automatically read; and
S603. the reference value increment is calculated according to an eighth calculation formula; and
the seventh calculation formula is:

$${Y}_{M} > 1 ,$$

and
the eighth calculation formula is:

$${D}_{Ref} = ( D - {Y}_{M} ) / {D}_{0} ,$$

D_{Ref} represents the reference value increment.

In this embodiment of the present disclosure, to achieve a reference value modification controlled by the fluctuation adjustment instruction, the reference value increment is calculated only when the fluctuation adjustment instruction is received.

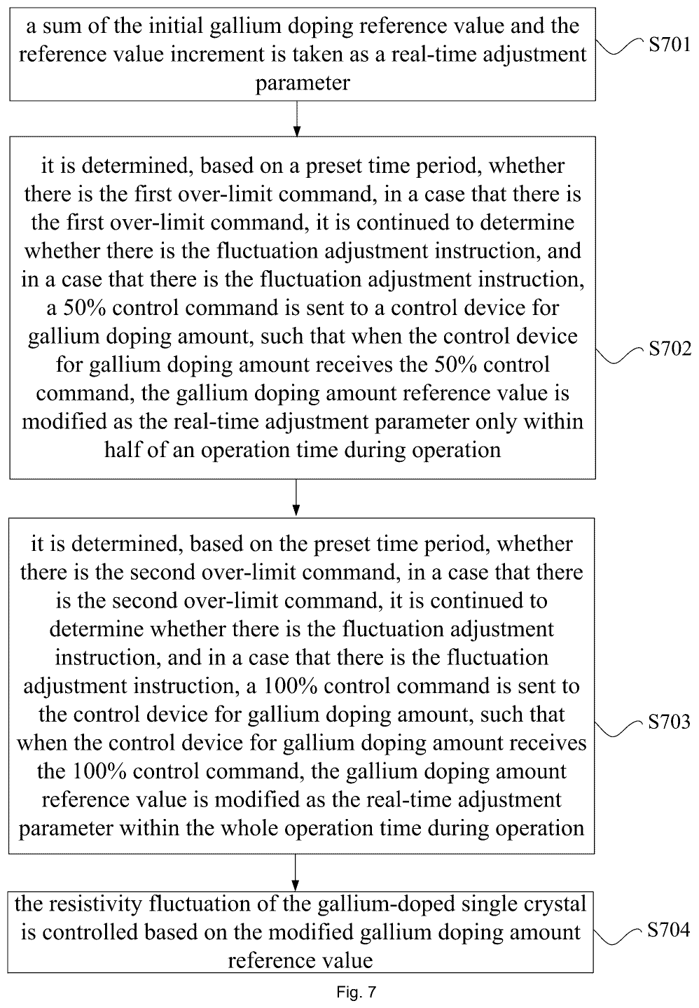

FIG. 7 is a flowchart of modifying the gallium doping amount reference value of the gallium-doped single crystal in real time based on the initial gallium doping reference value, the reference value increment, the first over-limit command, the second over-limit command, and the fluctuation adjustment instruction, and controlling the resistivity fluctuation of the gallium-doped single crystal based on the modified gallium doping amount reference value in the method for controlling resistivity based on the gallium content in the gallium-doped single crystal according to an embodiment of the present disclosure.

As shown in FIG. 7, in one or more embodiments, preferably, the gallium doping amount reference value of the gallium-doped single crystal is modified in real time based on the initial gallium doping reference value, the reference value increment, the first over-limit command, the second over-limit command, and the fluctuation adjustment instruction, and the resistivity fluctuation of the gallium-doped single crystal is controlled based on the modified gallium doping amount reference value includes the following steps:
S701. a sum of the initial gallium doping reference value and the reference value increment is taken as a real-time adjustment parameter;
S702. it is determined, based on a preset time period, whether there is the first over-limit command, in a case that there is the first over-limit command, it is continued to determine whether there is the fluctuation adjustment instruction, and in a case that there is the fluctuation adjustment instruction, a 50% control command is sent to a control device for gallium doping amount, such that when the control device for gallium doping amount receives the 50% control command, the gallium doping amount reference value is modified as the real-time adjustment parameter only within half of an operation time during operation;
S703. it is determined, based on the preset time period, whether there is the second over-limit command, in a case that there is the second over-limit command, it is continued to determine whether there is the fluctuation adjustment instruction, and in a case that there is the fluctuation adjustment instruction, a 100% control command is sent to the control device for gallium doping amount, such that when the control device for gallium doping amount receives the 100% control command, the gallium doping amount reference value is modified as the real-time adjustment parameter within the whole operation time during operation; and
S704. the resistivity fluctuation of the gallium-doped single crystal is controlled based on the modified gallium doping amount reference value.

In the embodiments of the present disclosure, dual control is implemented. Such control is based on a control command of a first level, including the first over-limit command and the second over-limit command. After this level is met, it is to be additionally determined whether the future prediction exceeds 1%. In a case that the future prediction does not exceed 1%, no additional control is needed. In a case that the future prediction exceeds 1%, the current real-time adjustment parameter needs to be modified. However, due to the different magnitudes of the first over-limit command and the second over-limit command, the actual control degrees vary. The control time for the 50% control command is shorter than that for the 100% control command, resulting in a smaller modification intensity.

A second aspect of the embodiments of the present disclosure provides a system for controlling resistivity based on gallium content in a gallium-doped single crystal.

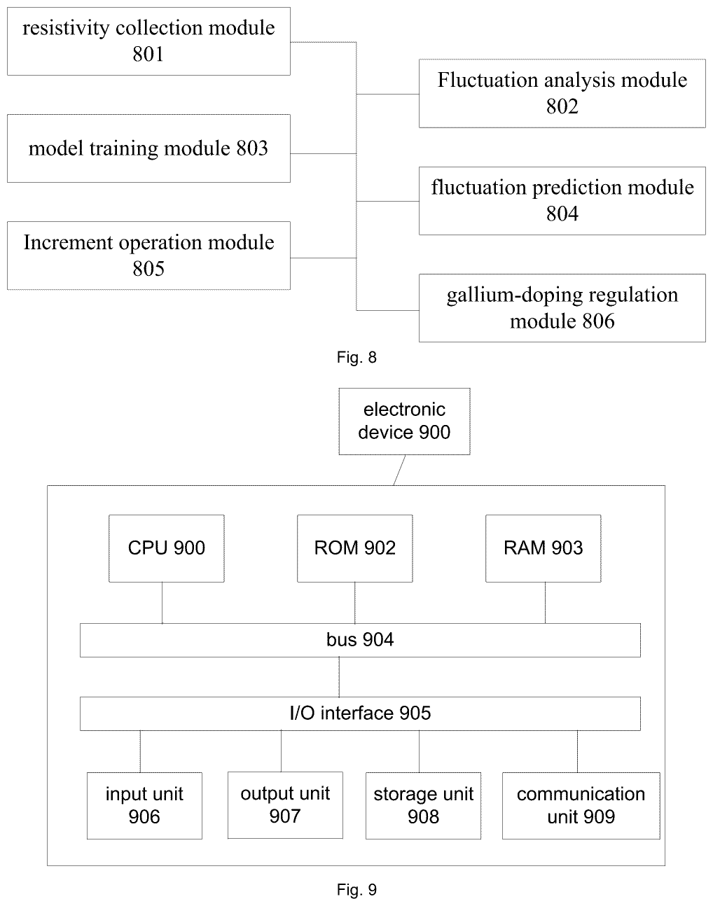

FIG. 8 is a structural diagram of a system for controlling resistivity based on gallium content in a gallium-doped single crystal according to an embodiment of the present disclosure.

In one or more embodiments, preferably, the system for controlling resistivity based on gallium content in a gallium-doped single crystal includes:
a resistivity collection module 801 configured to set an initial gallium doping reference value for the gallium-doped single crystal, and obtain resistivity measurement values of the gallium-doped single crystal in real time using a sensor;
a fluctuation analysis module 802 configured to send a first over-limit command and a second over-limit command when one of the resistivity measurement values satisfies a preset condition;
a model training module 803 configured to calculate a target optimal prediction coefficient group based on the resistivity measurement values;
a fluctuation prediction module 804 configured to calculate a target prediction value based on the target optimal prediction coefficient group;
an increment operation module 805 configured to perform online analysis based on the target prediction value to generate a reference value increment and a fluctuation adjustment instruction; and
a gallium-doping regulation module 806 configured to modify a gallium doping amount reference value of the gallium-doped single crystal in real time based on the initial gallium doping reference value, the reference value increment, the first over-limit command, the second over-limit command, and the fluctuation adjustment instruction, and control a resistivity fluctuation of the gallium-doped single crystal based on a modified gallium doping amount reference value, and
the first over-limit command and the second over-limit command are used for cooperation with the fluctuation adjustment instruction to enable real-time control of the gallium doping amount reference value; the target optimal prediction coefficient group is used for representing a prediction function coefficient set corresponding to most accurate prediction data; the target prediction value is prediction data obtained at a future t+1-th time point based on the target optimal prediction coefficient group; and the reference value increment is a real-time variation of the gallium doping amount reference value during real-time modification of the gallium doping amount reference value.

In this embodiment of the present disclosure, modification is achieved through modular design, where the modified value is an independent calculation value obtained from the difference between the resistivity of each segment and the target resistivity. The modified value is dynamic based on the target resistivity, enabling periodic and rapid modification.

Further, the resistivity collection module 801 includes:
a reference value calculation unit configured to set the initial gallium doping reference value based on a preset parameter of the gallium-doped single crystal;
a resistivity collection unit configured to measure resistivity of the gallium-doped single crystal in real time using a voltage sensor and a current sensor; and
a time mark setting unit configured to mark a time of the resistivity obtained through measurement, and take the resistivity after time marking as the resistivity measurement values.

Further, the fluctuation analysis module 802 includes:
an initial time point setting unit configured to set a resistivity measurement value at an initial time point;
a time point collection unit configured to read a resistivity measurement value, at a current time point, used as a resistivity measurement value at a t-th time point;
a fluctuation calculation unit configured to calculate the resistivity fluctuation according to a first calculation formula;
a first determining unit configured to determine whether the resistivity fluctuation satisfies a second calculation formula; and in a case that the resistivity fluctuation satisfies the second calculation formula, send the first over-limit command; or in a case that the resistivity fluctuation does not satisfy the second calculation formula, continue operation without processing; and
a second determining unit configured to determine whether the resistivity fluctuation satisfies a third calculation formula; and in a case that the resistivity fluctuation satisfies the third calculation formula, send the second over-limit command; or in a case that the resistivity fluctuation does not satisfy the third calculation formula, continue operation without processing.

The first calculation formula is:

$$B = {D}_{t} - {D}_{0} ,$$

B represents the resistivity fluctuation, Dₜ represents the resistivity measurement value at the t-th time point, and D₀ represents the resistivity measurement value at the initial time point.

The second calculation formula is:

$$B > {L}_{1} > 0.5 ,$$

L₁ represents a preset first resistivity fluctuation limit, and
the third calculation formula is:

$$B > {L}_{2} > 0.75 > {L}_{1} ,$$

and L₂ represents a preset second resistivity fluctuation limit.

Further, the model training module 803 includes:
a prediction coefficient setting unit configured to set a first prediction coefficient, a second prediction coefficient, a third prediction coefficient, a fourth prediction coefficient, and a fifth prediction coefficient;
a history collection unit configured to read stored historical data of the resistivity measurement values;
a resistivity predicting unit configured to calculate a predicted resistivity value according to a fourth calculation formula;
a coefficient analyzing unit configured to, based on the predicted resistivity value, calculate, according to a fifth calculation formula, a first target prediction coefficient, a second target prediction coefficient, a third target prediction coefficient, a fourth target prediction coefficient, and a fifth target prediction coefficient; and
a coefficient storing unit configured to store the first target prediction coefficient, the second target prediction coefficient, the third target prediction coefficient, the fourth target prediction coefficient, and the fifth target prediction coefficient as the target optimal prediction coefficient group; and
the fourth calculation formula is:

$${Y}_{t + 1} = {k}_{1} {D}_{t} + {k}_{2} {D}_{t - 1} + {k}_{3} {D}_{t - 2} + {k}_{4} {D}_{t - 3} + {k}_{5} {D}_{t - 4} + D ,$$

Yₜ₊₁ represents the predicted resistivity value at a t+1-th time point, Dₜ₋₁ represents the resistivity measurement value at a t−1-th time point, Dₜ₋₂ represents the resistivity measurement value at a t−2-th time point, Dₜ₋₃ represents the resistivity measurement value at a t−3-th time point, Dₜ₋₄ represents the resistivity measurement value at a t−4-th time point, D represents an average resistivity value, and k₁, k₂, k₃, k₄, and k₅ sequentially represent the first prediction coefficient, the second prediction coefficient, the third prediction coefficient, the fourth prediction coefficient, and the fifth prediction coefficient, respectively;
the fifth calculation formula is:

$$( {k}_{1 m} , {k}_{2 m} , {k}_{3 m} , {k}_{4 m} , {k}_{5 m} ) = arg min ( \vert {Y}_{t + 1} - {D}_{t + 1} \vert ) ,$$

argmin represents a coefficient corresponding to a target function when a minimum value of the target function is selected, Dₜ₊₁ represents an actual resistivity measurement value at the t+1-th time point, and k₁ₘ, k₂ₘ, k₃ₘ, k₄ₘ, and k₅ₘ sequentially represent the first target prediction coefficient, the second target prediction coefficient, the third target prediction coefficient, the fourth target prediction coefficient, and the fifth target prediction coefficient, respectively.

Further, the fluctuation prediction module 804 includes:
an average calculation unit configured to, based on the resistivity measurement value at the current time point and the historical data of the resistivity measurement values, calculate the average resistivity value; and
a target prediction unit configured to calculate the target prediction value according to a sixth calculation formula; and
the sixth calculation formula is:

$${Y}_{M} = {k}_{1 m} {D}_{t} + {k}_{2 m} {D}_{t - 1} + {k}_{3 m} {D}_{t - 2} + {k}_{4 m} {D}_{t - 3} + {k}_{5 m} {D}_{t - 4} + D ,$$

Y_{M} represents the target prediction value, and k₁ₘ, k₂ₘ, k₃ₘ, k₄ₘ, and k₅ₘ sequentially represent the first target prediction coefficient, the second target prediction coefficient, the third target prediction coefficient, the fourth target prediction coefficient, and the fifth target prediction coefficient, respectively.

Further, the increment operation module 805 includes:
a first instruction sending unit configured to determine whether the target prediction value satisfies a seventh calculation formula, and in a case that the target prediction value satisfies the seventh calculation formula, generate the fluctuation adjustment instruction;
a second instruction sending unit configured to, after the fluctuation adjustment instruction is generated, automatically read the resistivity measurement value at the initial time point and the average resistivity value; and
a reference increment unit configured to calculate the reference value increment according to an eighth calculation formula; and
the seventh calculation formula is:

$${Y}_{M} > 1 ,$$

and
the eighth calculation formula is:

$${D}_{Ref} = ( D - {Y}_{M} ) / {D}_{0} ,$$

D_{Ref} represents the reference value increment.

Further, the gallium-doping regulation module 806 includes:
a real-time adjusting unit configured to take a sum of the initial gallium doping reference value and the reference value increment as a real-time adjustment parameter;
a first over-limit unit configured to determine, based on a preset time period, whether there is the first over-limit command, in a case that there is the first over-limit command, continue to determine whether there is the fluctuation adjustment instruction, and in a case that there is the fluctuation adjustment instruction, send a 50% control command to a control device for gallium doping amount, such that when the control device for gallium doping amount receives the 50% control command, the gallium doping amount reference value is modified as the real-time adjustment parameter only within half of an operation time during operation;
a second over-limit unit configured to determine, based on the preset time period, whether there is the second over-limit command, in a case that there is the second over-limit command, continue to determine whether there is the fluctuation adjustment instruction, and in a case that there is the fluctuation adjustment instruction, send a 100% control command to the control device for gallium doping amount, such that when the control device for gallium doping amount receives the 100% control command, the gallium doping amount reference value is modified as the real-time adjustment parameter within the whole operation time during operation; and
a fluctuation control unit configured to control the resistivity fluctuation of the gallium-doped single crystal based on the modified gallium doping amount reference value.

A third aspect of the embodiments of the present disclosure provides a non-transitory computer-readable storage medium, storing a computer program instruction, where when the computer program instruction is executed by a processor, the method according to any one of the embodiments of the first aspect of the present disclosure is implemented.

A fourth aspect of the embodiments of the present disclosure provides an electronic device. FIG. 9 is a structural diagram of an electronic device according to an embodiment of the present disclosure. The electronic device shown in FIG. 9 is a general gallium-doping regulation apparatus. As shown in FIG. 9, the electronic device 900 includes a central processing unit (CPU) 901, which can execute various appropriate actions and processes according to computer program instructions stored in read-only memory (ROM) 902 or loaded into random access memory (RAM) 903 from a storage unit 908. Various programs and data required for the operation of the electronic device 900 can also be stored in RAM 903. The CPU 901, ROM 902, and RAM 903 are interconnected via a bus 904. An input/output (I/O) interface 905 is also connected to the bus 904.

Multiple modules in the electronic device 900 are connected to the I/O interface 905, including an input unit 906, an output unit 907, and a storage unit 908. The processing unit 901 executes various methods and processes described above, such as the method described according to the first aspect of the embodiment of the present disclosure. For example, in some embodiments, the method described according to the first aspect of the embodiments of the present disclosure can be implemented as a computer software program, which is stored in a machine-readable medium such as the storage unit 908. In some embodiments, part or all of the computer program can be loaded and/or installed onto the electronic device 900 via ROM 902 and/or a communication unit 909. When the computer program is loaded into RAM 903 and executed by CPU 901, one or more operations of the method described according to the first aspect of the embodiments of the present disclosure can be performed. Alternatively, in other embodiments, CPU 901 can be configured to perform one or more actions of the method described according to the first aspect of the embodiments of the present disclosure by any other appropriate means (for example, by means of firmware).

The technical solutions provided by the embodiments of the present disclosure can achieve the following beneficial effects:

In the solutions of the present disclosure, based on the collection of the current resistivity, automatic control of the gallium content in the gallium-doped single crystal is performed. Through automatic multi-level online control of the resistivity, a resistivity fluctuation of less than 1% is achieved.

The solutions of the present disclosure provide an online intelligent modification method for real-time online analysis of the resistivity fluctuation to obtain gallium content adjusted in real time.

Those skilled in the art should understand that the embodiments of the present disclosure may be provided as a method, a system, or a computer program product. Therefore, the present disclosure may use a form of hardware-only embodiments, software-only embodiments, or embodiments with a combination of software and hardware. Moreover, the present disclosure may use a form of a computer program product that is implemented on one or more computer-usable storage media, (which include but are not limited to a magnetic disk memory and a compact disc read-only memory), including computer-usable program code.

The present disclosure is described with reference to the flowcharts and/or block diagrams of the method, the device (system), and the computer program product according to the embodiments of the present disclosure. It should be understood that computer program instructions may be used to implement each process and/or each block in the flowcharts and/or the block diagrams and a combination of a process and/or a block in the flowcharts and/or the block diagrams. These computer program instructions may be provided for a general-purpose computer, a dedicated computer, an embedded processor, or a processor of any other programmable data processing device to generate a machine, such that the instructions executed by a computer or a processor of any other programmable data processing device generate an apparatus for implementing a specific function in one or more processes in the flowcharts and/or in one or more blocks in the block diagrams.

These computer program instructions may also be stored in a computer-readable memory that can instruct a computer or another programmable data processing device to work in a specific manner, such that the instructions stored in the computer-readable memory generate an artifact that includes an instruction apparatus. The instruction apparatus implements a specific function in one or more processes in the flowcharts and/or in one or more blocks in the block diagrams.

These computer program instructions may also be loaded onto a computer or another programmable data processing device, such that a series of operations and steps are performed on the computer or the another programmable device, thereby generating computer-implemented processing. Therefore, the instructions executed on the computer or the another programmable device provide steps for implementing a specific function in one or more processes in the flowcharts and/or in one or more blocks in the block diagrams.

Apparently, persons skilled in the art can make various changes and modifications to the present disclosure without departing from the spirit and scope of the present disclosure. In this way, the present disclosure is intended to cover these modifications and variations provided that they fall within the scope of protection defined by the claims of the present disclosure or equivalents thereof.

1. A method for controlling resistivity based on gallium content in a gallium-doped single crystal, comprising:
setting an initial gallium doping reference value for the gallium-doped single crystal, and obtaining resistivity measurement values of the gallium-doped single crystal in real time using a sensor;
sending a first over-limit command and a second over-limit command when one of the resistivity measurement values satisfies a preset condition;
calculating a target optimal prediction coefficient group based on the resistivity measurement values;
calculating a target prediction value based on the target optimal prediction coefficient group;
performing online analysis based on the target prediction value to generate a reference value increment and a fluctuation adjustment instruction; and
modifying a gallium doping amount reference value of the gallium-doped single crystal in real time based on the initial gallium doping reference value, the reference value increment, the first over-limit command, the second over-limit command, and the fluctuation adjustment instruction, and controlling a resistivity fluctuation of the gallium-doped single crystal based on a modified gallium doping amount reference value; wherein
the first over-limit command and the second over-limit command are used for cooperation with the fluctuation adjustment instruction to enable real-time control of the gallium doping amount reference value; the target optimal prediction coefficient group is used for representing a prediction function coefficient set corresponding to most accurate prediction data; the target prediction value is prediction data obtained at a future t+1-th time point based on the target optimal prediction coefficient group; and the reference value increment is a real-time variation of the gallium doping amount reference value during real-time modification of the gallium doping amount reference value.

2. The method for controlling resistivity based on the gallium content in the gallium-doped single crystal as claimed in claim 1, wherein setting the initial gallium doping reference value for the gallium-doped single crystal, and obtaining the resistivity measurement values of the gallium-doped single crystal in real time using the sensor comprises:
based on a preset parameter of the gallium-doped single crystal, setting the initial gallium doping reference value;
measuring, by a voltage sensor and a current sensor, resistivity of the gallium-doped single crystal in real time; and
marking a time of the resistivity obtained through measurement, and taking the resistivity after time marking as the resistivity measurement values.

3. The method for controlling resistivity based on the gallium content in the gallium-doped single crystal as claimed in claim 1, wherein sending the first over-limit command and the second over-limit command when one of the resistivity measurement values satisfies the preset condition comprises:
setting a resistivity measurement value at an initial time point;
reading a resistivity measurement value, at a current time point, used as a resistivity measurement value at a t-th time point;
calculating the resistivity fluctuation according to a first calculation formula;
determining whether the resistivity fluctuation satisfies a second calculation formula; and in a case that the resistivity fluctuation satisfies the second calculation formula, sending the first over-limit command; or in a case that the resistivity fluctuation does not satisfy the second calculation formula, continuing operation without processing; and
determining whether the resistivity fluctuation satisfies a third calculation formula; and in a case that the resistivity fluctuation satisfies the third calculation formula, sending the second over-limit command; or in a case that the resistivity fluctuation does not satisfy the third calculation formula, continuing operation without processing; wherein
the first calculation formula is:
$$B = {D}_{t} - {D}_{0} ,$$
B represents the resistivity fluctuation, Dₜ represents the resistivity measurement value at the t-th time point, and D₀ represents the resistivity measurement value at the initial time point; the second calculation formula is:
$$B > {L}_{1} > 0.5 ,$$
L₁ represents a preset first resistivity fluctuation limit; and
the third calculation formula is:
$$B > {L}_{2} > 0.75 > {L}_{1} ,$$
L₂ represents a preset second resistivity fluctuation limit.

4. The method for controlling resistivity based on the gallium content in the gallium-doped single crystal as claimed in claim 3, wherein calculating the target optimal prediction coefficient group based on the resistivity measurement values comprises:
setting a first prediction coefficient, a second prediction coefficient, a third prediction coefficient, a fourth prediction coefficient, and a fifth prediction coefficient;
reading stored historical data of the resistivity measurement values;
calculating a predicted resistivity value according to a fourth calculation formula;
based on the predicted resistivity value, calculating, according to a fifth calculation formula, a first target prediction coefficient, a second target prediction coefficient, a third target prediction coefficient, a fourth target prediction coefficient, and a fifth target prediction coefficient; and
storing the first target prediction coefficient, the second target prediction coefficient, the third target prediction coefficient, the fourth target prediction coefficient, and the fifth target prediction coefficient as the target optimal prediction coefficient group; wherein
the fourth calculation formula is:
$${Y}_{t + 1} = {k}_{1} {D}_{t} + {k}_{2} {D}_{t - 1} + {k}_{3} {D}_{t - 2} + {k}_{4} {D}_{t - 3} + {k}_{5} {D}_{t - 4} + D ,$$
Yₜ₊₁ represents the predicted resistivity value at a t+1-th time point, Dₜ₋₁ represents the resistivity measurement value at a t−1-th time point, Dₜ₋₂ represents the resistivity measurement value at a t−2-th time point, Dₜ₋₃ represents the resistivity measurement value at a t−3-th time point, Dₜ₋₄ represents the resistivity measurement value at a t−4-th time point, D represents an average resistivity value, and k₁, k₂, k₃, k₄, and k₅ sequentially represent the first prediction coefficient, the second prediction coefficient, the third prediction coefficient, the fourth prediction coefficient, and the fifth prediction coefficient, respectively; and
the fifth calculation formula is:
$$( {k}_{1 m} , {k}_{2 m} , {k}_{3 m} , {k}_{4 m} , {k}_{5 m} ) = arg min ( \vert {Y}_{t + 1} - {D}_{t + 1} \vert ) ,$$
argmin represents a function coefficient when a minimum value of a target function |Yₜ₊₁−Dₜ₊₁| is selected, Dₜ₊₁ represents an actual resistivity measurement value at the t+1-th time point, and k₁ₘ, k₂ₘ, k₃ₘ, k₄ₘ, and k₅ₘ sequentially represent the first target prediction coefficient, the second target prediction coefficient, the third target prediction coefficient, the fourth target prediction coefficient, and the fifth target prediction coefficient, respectively.

5. The method for controlling resistivity based on the gallium content in the gallium-doped single crystal as claimed in claim 4, wherein calculating the target prediction value based on the target optimal prediction coefficient group comprises:
based on the resistivity measurement value at the current time point and the historical data of the resistivity measurement values, calculating the average resistivity value; and
calculating the target prediction value according to a sixth calculation formula; wherein
the sixth calculation formula is:
$${Y}_{M} = {k}_{1 m} {D}_{t} + {k}_{2 m} {D}_{t - 1} + {k}_{3 m} {D}_{t - 2} + {k}_{4 m} {D}_{t - 3} + {k}_{5 m} {D}_{t - 4} + D ,$$
Y_{M} represents the target prediction value, and k₁ₘ, k₂ₘ, k₃ₘ, k₄ₘ, and k₅ₘ sequentially represent the first target prediction coefficient, the second target prediction coefficient, the third target prediction coefficient, the fourth target prediction coefficient, and the fifth target prediction coefficient, respectively.

6. The method for controlling resistivity based on the gallium content in the gallium-doped single crystal as claimed in claim 5, wherein performing online analysis based on the target prediction value to generate the reference value increment and the fluctuation adjustment instruction comprises:
determining whether the target prediction value satisfies a seventh calculation formula, and in a case that the target prediction value satisfies the seventh calculation formula, generating the fluctuation adjustment instruction;
after the fluctuation adjustment instruction is generated, automatically reading the resistivity measurement value at the initial time point and the average resistivity value; and
calculating the reference value increment according to an eighth calculation formula; wherein
the seventh calculation formula is:
$${Y}_{M} > 1 ,$$
and
the eighth calculation formula is:
$${D}_{Ref} = ( D - {Y}_{M} ) / {D}_{0} ,$$
D_{Ref} represents the reference value increment.

7. The method for controlling resistivity based on the gallium content in the gallium-doped single crystal as claimed in claim 1, wherein modifying the gallium doping amount reference value of the gallium-doped single crystal in real time based on the initial gallium doping reference value, the reference value increment, the first over-limit command, the second over-limit command, and the fluctuation adjustment instruction, and controlling the resistivity fluctuation of the gallium-doped single crystal based on the modified gallium doping amount reference value comprises:
taking a sum of the initial gallium doping reference value and the reference value increment as a real-time adjustment parameter;
determining, based on a preset time period, whether there is the first over-limit command, in a case that there is the first over-limit command, continuing to determine whether there is the fluctuation adjustment instruction, and in a case that there is the fluctuation adjustment instruction, sending a 50% control command to a control device for gallium doping amount, such that when the control device for gallium doping amount receives the 50% control command, the gallium doping amount reference value is modified as the real-time adjustment parameter only within half of an operation time during operation;
determining, based on the preset time period, whether there is the second over-limit command, in a case that there is the second over-limit command, continuing to determine whether there is the fluctuation adjustment instruction, and in a case that there is the fluctuation adjustment instruction, sending a 100% control command to the control device for gallium doping amount, such that when the control device for gallium doping amount receives the 100% control command, the gallium doping amount reference value is modified as the real-time adjustment parameter within the whole operation time during operation; and
controlling the resistivity fluctuation of the gallium-doped single crystal based on the modified gallium doping amount reference value.

8. A system for controlling resistivity based on gallium content in a gallium-doped single crystal, comprising:
a resistivity collection module configured to set an initial gallium doping reference value for the gallium-doped single crystal, and obtain resistivity measurement values of the gallium-doped single crystal in real time using a sensor;
a fluctuation analysis module configured to send a first over-limit command and a second over-limit command when one of the resistivity measurement values satisfies a preset condition;
a model training module configured to calculate a target optimal prediction coefficient group based on the resistivity measurement values;
a fluctuation prediction module configured to calculate a target prediction value based on the target optimal prediction coefficient group;
an increment operation module configured to perform online analysis based on the target prediction value to generate a reference value increment and a fluctuation adjustment instruction; and
a gallium-doping regulation module configured to modify a gallium doping amount reference value of the gallium-doped single crystal in real time based on the initial gallium doping reference value, the reference value increment, the first over-limit command, the second over-limit command, and the fluctuation adjustment instruction, and control a resistivity fluctuation of the gallium-doped single crystal based on a modified gallium doping amount reference value; wherein
the first over-limit command and the second over-limit command are used for cooperation with the fluctuation adjustment instruction to enable real-time control of the gallium doping amount reference value; the target optimal prediction coefficient group is used for representing a prediction function coefficient set corresponding to most accurate prediction data; the target prediction value is prediction data obtained at a future t+1-th time point based on the target optimal prediction coefficient group; and the reference value increment is a real-time variation of the gallium doping amount reference value during real-time modification of the gallium doping amount reference value.

9. A non-transitory computer-readable storage medium, storing a computer program instruction, wherein when the computer program instruction is executed by a processor, the computer program instruction is configured to cause the processor to:
set an initial gallium doping reference value for the gallium-doped single crystal, and obtain resistivity measurement values of the gallium-doped single crystal in real time using a sensor;
send a first over-limit command and a second over-limit command when one of the resistivity measurement values satisfies a preset condition;
calculate a target optimal prediction coefficient group based on the resistivity measurement values;
calculate a target prediction value based on the target optimal prediction coefficient group;
perform online analysis based on the target prediction value to generate a reference value increment and a fluctuation adjustment instruction; and
modify a gallium doping amount reference value of the gallium-doped single crystal in real time based on the initial gallium doping reference value, the reference value increment, the first over-limit command, the second over-limit command, and the fluctuation adjustment instruction, and control a resistivity fluctuation of the gallium-doped single crystal based on a modified gallium doping amount reference value; wherein
the first over-limit command and the second over-limit command are used for cooperation with the fluctuation adjustment instruction to enable real-time control of the gallium doping amount reference value; the target optimal prediction coefficient group is used for representing a prediction function coefficient set corresponding to most accurate prediction data; the target prediction value is prediction data obtained at a future t+1-th time point based on the target optimal prediction coefficient group; and the reference value increment is a real-time variation of the gallium doping amount reference value during real-time modification of the gallium doping amount reference value.

10. An electronic device, comprising a memory and a processor, wherein the memory is configured to store one or more computer program instructions, and the one or more computer program instructions are executed by the processor to implement the method as claimed in claim 1.

11. The non-transitory computer-readable storage medium as claimed in claim 9, wherein setting the initial gallium doping reference value for the gallium-doped single crystal, and obtaining the resistivity measurement values of the gallium-doped single crystal in real time using the sensor comprises:
based on a preset parameter of the gallium-doped single crystal, setting the initial gallium doping reference value;
measuring, by a voltage sensor and a current sensor, resistivity of the gallium-doped single crystal in real time; and
marking a time of the resistivity obtained through measurement, and taking the resistivity after time marking as the resistivity measurement values.

12. The non-transitory computer-readable storage medium as claimed in claim 9, wherein sending the first over-limit command and the second over-limit command when one of the resistivity measurement values satisfies the preset condition comprises:
setting a resistivity measurement value at an initial time point;
reading a resistivity measurement value, at a current time point, used as a resistivity measurement value at a t-th time point;
calculating the resistivity fluctuation according to a first calculation formula;
determining whether the resistivity fluctuation satisfies a second calculation formula; and in a case that the resistivity fluctuation satisfies the second calculation formula, sending the first over-limit command; or in a case that the resistivity fluctuation does not satisfy the second calculation formula, continuing operation without processing; and
determining whether the resistivity fluctuation satisfies a third calculation formula; and in a case that the resistivity fluctuation satisfies the third calculation formula, sending the second over-limit command; or in a case that the resistivity fluctuation does not satisfy the third calculation formula, continuing operation without processing; wherein
the first calculation formula is:
$$B = {D}_{t} - {D}_{0} ,$$
B represents the resistivity fluctuation, Dₜ represents the resistivity measurement value at the t-th time point, and D₀ represents the resistivity measurement value at the initial time point; the second calculation formula is:
$$B > {L}_{1} > 0.5 ,$$
L₁ represents a preset first resistivity fluctuation limit; and
the third calculation formula is:
$$B > {L}_{2} > 0.75 > {L}_{1} ,$$
L₂ represents a preset second resistivity fluctuation limit.

13. The non-transitory computer-readable storage medium as claimed in claim 12, wherein calculating the target optimal prediction coefficient group based on the resistivity measurement values comprises:
setting a first prediction coefficient, a second prediction coefficient, a third prediction coefficient, a fourth prediction coefficient, and a fifth prediction coefficient;
reading stored historical data of the resistivity measurement values;
calculating a predicted resistivity value according to a fourth calculation formula;
based on the predicted resistivity value, calculating, according to a fifth calculation formula, a first target prediction coefficient, a second target prediction coefficient, a third target prediction coefficient, a fourth target prediction coefficient, and a fifth target prediction coefficient; and
storing the first target prediction coefficient, the second target prediction coefficient, the third target prediction coefficient, the fourth target prediction coefficient, and the fifth target prediction coefficient as the target optimal prediction coefficient group; wherein
the fourth calculation formula is:
$${Y}_{t + 1} = {k}_{1} {D}_{t} + {k}_{2} {D}_{t - 1} + {k}_{3} {D}_{t - 2} + {k}_{4} {D}_{t - 3} + {k}_{5} {D}_{t - 4} + D ,$$
Yₜ₊₁ represents the predicted resistivity value at a t+1-th time point, Dₜ₋₁ represents the resistivity measurement value at a t−1-th time point, Dₜ₋₂ represents the resistivity measurement value at a t−2-th time point, Dₜ₋₃ represents the resistivity measurement value at a t−3-th time point, Dₜ₋₄ represents the resistivity measurement value at a t−4-th time point, D represents an average resistivity value, and k₁, k₂, k₃, k₄, and k₅ sequentially represent the first prediction coefficient, the second prediction coefficient, the third prediction coefficient, the fourth prediction coefficient, and the fifth prediction coefficient, respectively; and
the fifth calculation formula is:
$$( {k}_{1 m} , {k}_{2 m} , {k}_{3 m} , {k}_{4 m} , {k}_{5 m} ) = arg min ( \vert {Y}_{t + 1} - {D}_{t + 1} \vert ) ,$$
argmin represents a function coefficient when a minimum value of a target function |Yₜ₊₁−Dₜ₊₁| is selected, Dₜ₊₁ represents an actual resistivity measurement value at the t+1-th time point, and k₁ₘ, k₂ₘ, k₃ₘ, k₄ₘ, and k₅ₘ sequentially represent the first target prediction coefficient, the second target prediction coefficient, the third target prediction coefficient, the fourth target prediction coefficient, and the fifth target prediction coefficient, respectively.

14. The non-transitory computer-readable storage medium as claimed in claim 13, wherein calculating the target prediction value based on the target optimal prediction coefficient group comprises:
based on the resistivity measurement value at the current time point and the historical data of the resistivity measurement values, calculating the average resistivity value; and
calculating the target prediction value according to a sixth calculation formula; wherein the sixth calculation formula is:
$${Y}_{M} = {k}_{1 m} {D}_{t} + {k}_{2 m} {D}_{t - 1} + {k}_{3 m} {D}_{t - 2} + {k}_{4 m} {D}_{t - 3} + {k}_{5 m} {D}_{t - 4} + D ,$$
Y_{M} represents the target prediction value, and k₁ₘ, k₂ₘ, k₃ₘ, k₄ₘ, and k₅ₘ sequentially represent the first target prediction coefficient, the second target prediction coefficient, the third target prediction coefficient, the fourth target prediction coefficient, and the fifth target prediction coefficient, respectively.

15. The non-transitory computer-readable storage medium as claimed in claim 14, wherein performing online analysis based on the target prediction value to generate the reference value increment and the fluctuation adjustment instruction comprises:
determining whether the target prediction value satisfies a seventh calculation formula, and in a case that the target prediction value satisfies the seventh calculation formula, generating the fluctuation adjustment instruction;
after the fluctuation adjustment instruction is generated, automatically reading the resistivity measurement value at the initial time point and the average resistivity value; and
calculating the reference value increment according to an eighth calculation formula; wherein
the seventh calculation formula is:
$${Y}_{M} > 1 ,$$
and
the eighth calculation formula is:
$${D}_{Ref} = ( D - {Y}_{M} ) / {D}_{0} ,$$
D_{Ref} represents the reference value increment.

16. The non-transitory computer-readable storage medium as claimed in claim 9, wherein modifying the gallium doping amount reference value of the gallium-doped single crystal in real time based on the initial gallium doping reference value, the reference value increment, the first over-limit command, the second over-limit command, and the fluctuation adjustment instruction, and controlling the resistivity fluctuation of the gallium-doped single crystal based on the modified gallium doping amount reference value comprises:
taking a sum of the initial gallium doping reference value and the reference value increment as a real-time adjustment parameter;
determining, based on a preset time period, whether there is the first over-limit command, in a case that there is the first over-limit command, continuing to determine whether there is the fluctuation adjustment instruction, and in a case that there is the fluctuation adjustment instruction, sending a 50% control command to a control device for gallium doping amount, such that when the control device for gallium doping amount receives the 50% control command, the gallium doping amount reference value is modified as the real-time adjustment parameter only within half of an operation time during operation;
determining, based on the preset time period, whether there is the second over-limit command, in a case that there is the second over-limit command, continuing to determine whether there is the fluctuation adjustment instruction, and in a case that there is the fluctuation adjustment instruction, sending a 100% control command to the control device for gallium doping amount, such that when the control device for gallium doping amount receives the 100% control command, the gallium doping amount reference value is modified as the real-time adjustment parameter within the whole operation time during operation; and
controlling the resistivity fluctuation of the gallium-doped single crystal based on the modified gallium doping amount reference value.
